(19) United States
(12) Patent Application Publication
(10) Pub. No.: US 2024/0046006 A1
(43) Pub. Date: Feb. 8, 2024

(54) METHOD AND SYSTEM FOR MODELING, CALIBRATION, AND SIMULATION OF MULTI-STAGE SERIES PHOTORESIST CHARACTERIZATION NETWORK

(71) Applicant: Wuhan Yuwei Optical Software Co., Ltd., Wuhan (CN)

(72) Inventors: Haiqing Wei, Wuhan (CN); Xianhua Ke, Wuhan (CN)

(21) Appl. No.: 17/937,972

(22) Filed: Oct. 4, 2022

(30) Foreign Application Priority Data
Aug. 3, 2022 (CN) 2022109285472

(51) Int. Cl. G06F 30/20

(52) U.S. Cl. CPC G06F 30/20

(57) ABSTRACT

Disclosed in the invention are a method and system for modeling, calibration, and simulation of a multi-stage series photoresist characterization network, pertaining to the field of semiconductor lithography. The invention comprises: firstly dividing a photoresist reaction process into several key stages, using a new idea of modeling a multi-stage series system network, constructing multiple stages of series Wiener-Padé form sub-cascading modules according to characteristics of lithography processes, and utilizing a joint calibration strategy based on a constrained quadratic convex optimization algorithm to provide a simulation means based on library matching and low-order multivariate polynomial equivalence of model parameters. The invention emphasizes and leverages universal advantages of the Wiener-Padé system theory in the characterization of non-linear system response characteristics, thereby achieving accurate and efficient modeling and calibration of complex physical, optical, and chemical highly-nonlinear response characteristics of photoresists in different process flows, while avoiding over-fitting and reducing model complexity and redundancy.

### TECHNICAL FIELD

The present invention pertains to the field of semiconductor lithography, and more particularly, relates to a method and system for modeling, calibration, and simulation of a multi-stage series photoresist characterization network.

### BACKGROUND ART

Integrated circuit (IC) manufacturing is the core of the electronic information industry, a strategic, fundamental, and leading industry that supports economic and social development and safeguards national security. A photolithography process is one of the most critical processes in IC manufacturing, which is used to transfer a mask pattern to a photoresist coated on a silicon wafer without distortion through a photolithography imaging system. However, with the continuous development of IC manufacturing nodes, the optical proximity effect of lithography imaging systems has become increasingly more significant. Therefore, mask optimization technology is required before lithography mask manufacturing at a 90 nm node and below, so as to ensure the chip yield, performance, and manufacturability. In mask optimization technology, a photoresist model is a key link connecting an optical imaging system and final chip performance, which determines the precision of a photolithography process. In addition, photoresist models involve complex interactions between light and matter and structures as well as nonlinear physicochemical changes across time scales. Universal, correct, and efficient modeling of photoresists is an issue that urgently needs to be addressed in the development of mask optimization technology applicable to advanced IC manufacturing nodes.

The photoresist model is a key model used to describe a series of complex nonlinear physical and chemical processes inside a photoresist and the formation of micro-nano patterns in mask optimization technology, which plays a key role in photolithography process analysis, photolithography result prediction and calibration, and other issues, and requires fast speeds and high accuracy. A photoresist model that uses strict theoretical methods to simulate the physical and chemical effects of highly non-linear photolysis exposure, reaction diffusion, and photopolymerization that occur in an actual photoresist processing process, in spite of stringency and accuracy characteristics, cannot be applied to applications such as mask optimization that require both computational accuracy and efficiency due to high complexity, low computational efficiency and other reasons. At present, the most commonly used semi-empirical threshold model in industry has the advantages of simple modeling and fast calculation speeds, but lacks an accurate description of the actual physical and chemical properties of photoresists, which will introduce large errors in advanced IC manufacturing nodes. With the development of computer technology, photoresist models based on deep learning neural networks have gradually become widely used. Although such models can better achieve the characterization of internal physical and chemical reactions and mechanical deformations of photoresists, and unknown effects not included in strict photoresist models, the simulation progresses of the models are heavily dependent on training samples, and large calculation and simulation errors often occur when the models are dealing with problems such as layout translation, rotation, and symmetrical transformation. In addition, in order to obtain a more universal photoresist model, a large number of samples in different scenarios need to be trained, and a calibration process is complicated and time-consuming.

Therefore, in order to meet the development needs of advanced IC manufacturing technology, more accurate, efficient, and universal photoresist model modeling and calibration methods are desired.

### SUMMARY OF THE INVENTION

In view of the defects of the prior art, the purpose of the present invention is to provide a method and a system for modeling, calibration, and simulation of a multi-stage series photoresist characterization network, aiming to solve the problems of large calculation and simulation errors and complex and time-consuming calibration processes.

In order to achieve the above purpose, in a first aspect, the present invention provides a method for modeling a multi-stage series photoresist characterization system network. The method comprises:
S1, receiving designation of one or a plurality of target photoresist processes;
S2, establishing a corresponding series model for each target photoresist process; and
S3, cascading each series model according to a process sequence to form the multi-stage series characterization system network, where
step S2 comprises:
S21, receiving designation of the number of sub-cascading modules;
S22, constructing each Wiener-Padé form sub-cascading module; and
S23, sequentially connecting each Wiener-Padé form sub-cascading module in series to obtain a series model;
step S22 comprises:
S221, receiving designation of Wiener nonlinear orders, and kernel function types and quantities of a numerator and a denominator in a Padé approximation;
S222, convolving, according to the kernel function types and quantities of the numerator and the denominator, an output result of a previous-stage Wiener-Padé form sub-cascading module with selected kernel functions of the numerator and the denominator in the Padé approximation, to obtain base function terms of the numerator and the denominator;
S223, multiplying point by point, according to the Wiener nonlinear orders of the numerator and the denominator in the Padé approximation, base function term permutations and combinations of the numerator and the denominator to obtain base function terms of different orders in the numerator and the denominator;
S224, acquiring Wiener coefficients of the numerator and the denominator in the Padé approximation, and performing weighted summation on the base function terms of the different orders in the numerator and the denominator to obtain a numerator Wiener sum function term and a denominator Wiener sum function term; and
S225, constructing the numerator Wiener sum function term and the denominator Wiener sum function term in a Padé approximation form to obtain a Wiener-Padé form sub-cascading module.

Preferably, the Wiener-Padé form sub-cascading modules are specifically as follows:

$${M}_{W P n} [ {J}_{n - 1} ( x , y ) ] = \frac{{W}_{S}^{m} ( x , y )}{{W}_{S}^{d} ( x , y )} , {W}_{S}^{d} ( x , y ) \geq ε ( x , y ) > 0 or$$

$${M}_{W P n} [ {J}_{n - 1} ( x , y ) ] = \frac{{W}_{S}^{m} ( x , y )}{E + {W}_{S}^{d} ( x , y )} , E + {W}_{S}^{d} ( x , y ) \geq ε ( x , y ) > 0$$

wherein M_{WPn} represents a current Wiener-Padé form sub-cascading module, Jₙ₋₁(x, y) represents an output result of a previous-stage Wiener-Padé form sub-cascading module, Wₛ^{m}(x, y) represents the numerator Wiener sum function term, Wₛ^{d}(x, y) represents the denominator Wiener sum function term, ε(x, y) represents a set positive threshold matrix to avoid an ill-conditioned Padé approximation, E represents a matrix where all elements are 1, and an previous-stage input to the first-stage Wiener-Padé form cascading module is an original photoresist internal light intensity distribution.

It should be noted that the present invention prefers the aforementioned Wiener-Padé form sub-cascading modules, because such modules emphasize and combine the Wiener system characterization theory and the universal advantages of rational function Padé approximation methods in the characterization of nonlinear system response characteristics, such that the complex and changeable nonlinear response characteristics of the photoresist can be characterized more accurately with less Wiener terms while consuming less computing resources.

Preferably, outputs of the Wiener-Padé form sub-cascading modules are as follows:

Jₙ(x,y)=β₀M_{WPn}[Jₙ₋₁(x,y)]+β₁[I(x,y)⊗k(x,y)]
wherein Jₙ(x, y) and Jₙ₋₁(x, y) represent outputs of the current and previous-stage sub-cascading modules respectively, β₀ and β₁ represent weighting coefficients between the output of the previous-stage sub-cascading module and an action of the current module, I(x, y) represents the original photoresist internal light intensity distribution, and k(x, y) represents a convolution kernel with the original photoresist internal light intensity distribution.

It should be noted that the present invention prefers the outputs of the aforementioned Wiener-Padé sub-cascading modules, and the newly added Wiener-Padé sub-cascading modules not only contain the high-order nonlinear response components of the photoresist, but also retain a certain proportion of the original photoresist light intensity distribution components, enabling the Wiener-Padé sub-cascading modules to maintain efficient and stable convergence characteristics while conforming to physical reality.

In order to achieve the above purpose, in a second aspect, the present invention provides a method for calibrating a multi-stage series photoresist characterization system network, the multi-stage series photoresist characterization system network being constructed using the method described in the first aspect. The calibration method comprises:
T1, acquiring measured photoresist profile or critical dimension data; and
T2, using a joint calibration method based on a constrained quadratic convex optimization algorithm, cyclically comparing simulated photoresist profile or critical dimension data with the measured photoresist profile or critical dimension data, and sequentially calibrating a parameter of each sub-cascading module in the multi-stage series photoresist characterization system network.

Preferably, step T2 comprises:
T20, initializing a current process as the first target process;
T21, initializing a current module as the first Wiener-Padé sub-cascading module of the current process;
T22, determining a parameter to be calibrated for the current module, and randomly generating a set of non-zero parameters to be calibrated for the current process;
T23, determining whether the current process is the first target process, and if so, directly proceeding to T25; otherwise, proceeding to T24;
T24, using the parameter obtained by calibration to fix the states of all sub-cascading modules preceding the current process, and using preset parameters to set a sub-cascading module following the current process to an identity equation or a simple linear operator, and proceeding to T25;
T25, bringing the set of parameters to be calibrated into the current module to complete updating of the entire photoresist characterization system network;
T26, inputting the original photoresist internal light intensity distribution into the updated characterization system network, acquiring an output result of the last-stage sub-cascading module, and in conjunction with a photoresist threshold, acquiring the simulated photoresist profile or critical dimension data;
T27, comparing the photoresist profile or critical dimension data obtained by simulation with the corresponding measured data; if a current process accuracy convergence condition is not met, updating the calibrated parameter set and returning to step T25; otherwise, determining whether the current module is the last-stage sub-cascading module of the current process, and if so, proceeding to T28; otherwise, updating the current module to a next sub-cascading module of the current process and proceeding to step T22; and
T28, determining whether the current process is a final target process, and if so, indicating that the system network calibration is concluded; otherwise, updating the current process to the next target process, and proceeding to step T21.

It should be noted that the present invention prefers the above calibration method. By utilizing the clear hierarchical structure of the established photoresist characterization system network, since only a certain Wiener-Padé sub-cascading module in the characterization system network is calibrated each time, the obtained calibration results can make the model more in line with the actual physical situations while reducing the difficulty of calibrating the system characterization model and quickly converging to an optimal solution.

Preferably, the using preset parameters to set a sub-cascading module following the current process to an identity equation or a simple linear operator in step T24 is any of the following:
1) setting each Wiener coefficient in a Padé approximation numerator of the sub-cascading module to 0 or setting the first term of a weighting coefficient between an output of a previous sub-cascading module and an action of the current module to 0, such that the module is equivalent to an operator that only scales an input signal in an equal proportion;
2) directly treating the sub-cascading module as an equivalent unit operator, that is, outputting an input signal as it is; and
3) treating the sub-cascading module as an equivalent bias operator, that is, performing addition or subtraction with respect to an input signal as a whole by the same constant.

It should be noted that the present invention achieves efficient, independent, and decoupled hierarchical calibration of the photoresist characterization network by performing simple identity equation or linear operator equivalence on the sub-cascading modules to be calibrated.

Preferably, the method for data comparison in step T27 is specifically as follows:
T271, upsampling an output result of the last Wiener-Padé form sub-cascading module;
T272, using a photoresist reaction threshold T to truncate the upsampled final output result into a simulated binary image I₂ₛ(x, y);
extracting from the output result a light intensity distribution curve L(x, y) on a ruler, extracting a critical dimension endpoint Pᵢ(x, y) by using {Pᵢ(x, y); [L(Pᵢ)−T]*[L(Pᵢ₊₁)−T]<0}, and calculating the distance between two endpoints as the simulated critical dimension data CDₛ, wherein L(Pᵢ) represents a light intensity value at a critical dimension endpoint on the light intensity distribution curve;
T273, converting the measured profile to a binary image I₂ₘ(x, y) with inner 1 and outer 0, and performing an XOR Boolean operation on I₂ₘ(x, y) and I₂ₛ(x, y) to obtain a profile difference map I₂ₒᵣ(x, y), and evaluating a simulated profile extraction result by using the following formula:

$$Δ E P E = \frac{N u m [ {I}_{2 or} ( x , y ) = 1 ]}{N u m [ {I}_{2 or} ( x , y ) ]} {d}_{pixel}$$

wherein Num represents a pixel count function, the numerator in the above formula is the number of counted pixels with a value of 1, the denominator in the above formula is the total number of counted pixels in the binary image, and dₚᵢₓₑₗ represents the length of each pixel;
evaluating a simulated critical dimension data extraction result by using the following formula:

$$Δ E P E = \sqrt{\frac{{\sum }_{1}^{N} {( C {D}_{s} - C {D}_{m} )}^{2}}{N}}$$

where CDₛ and CDₘ represent the simulated and measured critical dimensions respectively, and N is the total number of CDₘ.

It should be noted that the present invention supports two different calibration modes based on the measured profile and critical dimension data existing in the photoresist calibration process by providing two different measured and simulated data comparison and evaluation methods.

Preferably, for comparison and evaluation between the simulated photoresist profile and the measured profile, a constrained quadratic convex optimization algorithm is used to obtain by comparison the difference between a light intensity distribution corresponding to an actual profile point in the output result of the last stage sub-cascading module and a threshold:

$$\{ \begin{matrix}{‖ {W}_{S}^{m} [ C ( x , y ) ] - T \cdot \{ E + {W}_{S}^{d} [ C ( x , y ) ] \} ‖}_{1 / 2 / ∞} \leq {δ}_{C} \cdot \{ E + {W}_{S}^{d} [ C ( x , y ) ] \} \\ E + {W}_{S}^{d} ( x , y ) \geq ε ( x , y ) > 0\end{matrix} \}$$

for comparison and evaluation between the simulated photoresist critical dimension and the measured photoresist critical dimension, a constrained quadratic convex optimization algorithm is used to compare and measure the differences between measured light intensity distributions at two ends C and D and the threshold:

$${‖ \frac{{M}_{WPn} [ CD ( {P}_{1} ) ] - T}{{M}_{WPn}^{′} [ CD ( {P}_{1} ) ]} - \frac{{M}_{WPn} [ CD ( {P}_{2} ) ] - T}{{M}_{WPn}^{′} [ CD ( {P}_{2} ) ]} + \vert {P}_{2} - {P}_{1} \vert - {CD}_{m} ‖}_{1 / 2 / ∞} \leq {δ}_{CD}$$

wherein Wₛ^{m}(x, y) represents a numerator Wiener sum function term, Wₛ^{d}(x, y) represents a denominator Wiener sum function term, C(x, y) represents the simulated profile obtained by performing edge extraction on the simulation binary image, T represents a photoresist reaction threshold, E represents a matrix where all elements are 1, δ_{CD} represents a convergence threshold between the simulated profile and the measured profile; ∥ ∥_{1/2/∞} represents a 1 norm, a 2 norm, or an infinite norm; M_{WPn} represents the current Wiener-Padé form sub-cascading module, M′_{WPn} represents the derivative of the output result of the last-stage sub-cascading module in the CD direction, CD( ) represents the coordinates at the critical end point; P₁ and P₂ represent the two endpoints of the measured critical dimension, respectively.

In order to achieve the above purpose, in a third aspect, the present invention provides a method for efficient online simulation of a photoresist profile. The simulation method comprises:
R1, acquiring photoresist profile or critical dimension data under discrete distributions of different process parameters in different variation intervals;
R2, using measured data in a variation interval of the same process parameter as an input, using the calibration method according to the second aspect to repeatedly correct a photoresist characterization system network, so as to obtain a coefficient of each Wiener-Padé form sub-cascading module at each stage in the resist characterization system network and a photoresist internal light intensity distribution under discrete variation of the process parameter;
R3, performing, according to the variation regularity of coefficients of different sub-cascading modules, low-order multivariate polynomial equivalence on the discretely varying module coefficients, and establishing a coefficient library of the sub-cascading modules under continuous variation of the process parameter;
R4, acquiring a light intensity distribution under any process parameter condition in the discrete variation interval of the process parameter by using an interpolation method, and establishing a photoresist internal light intensity distribution library under continuous variation of the process parameter;
R5, repeating steps R1 to R4 to establish a module coefficient library and a photoresist internal light intensity distribution library corresponding to continuous variation of target process parameter combinations; and
R6, at a simulation stage, using a process parameter combination set for simulation as an index, using a library matching method to extract a corresponding system parameter and photoresist internal light intensity distribution under the process condition, and bringing the system parameter and internal light intensity distribution into the photoresist characterization system network, to perform efficient online simulation prediction and evaluation of a photoresist profile.

In order to achieve the above purpose, in a fourth aspect, the present invention provides a system for efficient online simulation of a photoresist profile, comprising: a processor and a memory;
the memory being configured to store a computer program or instructions;
   and the processor being configured to execute the computer program or instructions in the memory such that the method of the third aspect is performed.

In general, compared with the prior art, the above technical solutions conceived by the present invention have the following beneficial effects:

(1) The present invention proposes a method for modeling a multi-stage series photoresist characterization system network, which constructs multiple stages of series Wiener-Padé sub-cascading modules according to the characteristics of each lithography process, so as to achieve step-by-step and accurate description of the complex physical, optical, and chemical highly non-linear response characteristics of a photoresist under different process flows, while avoiding over-fitting and reducing model complexity and redundancy.

(2) The present invention proposes a method for calibrating a multi-stage series photoresist characterization system network. By treating a photoresist model calibration problem as an equivalent constrained quadratic convex optimization problem, the property of unique local optimum equal to global optimum of a constrained quadratic convexity optimization algorithm and the convex set separation theorem are leveraged, thereby achieving photoresist model calibration with different optimization objectives and optimization accuracy.

(3) The present invention proposes a method and system for efficient online simulation of a photoresist profile, utilizing a method of low-order multivariate polynomial equivalent and continuous interpolation of model parameters, so as to enable establishment of a photoresist characterization network model library with multiple continuously varying process parameters from experimental data obtained from only measured discrete process conditions. In addition, the simulation strategy based on library matching achieves efficient online simulation under variation of multiple process parameters.

### BRIEF DESCRIPTION OF THE DRAWINGS

FIG. 1 is a schematic diagram of the inventive concept of universal photoresist modeling and calibration based on a Wiener-Padé multi-stage series system network provided by the present invention.

FIG. 2 is a flowchart of a method for modeling a multi-stage series photoresist characterization system network provided by the present invention.

FIG. 3 is a flowchart of a method for calibrating a multi-stage series photoresist characterization system network provided by the present invention.

FIG. 4 is a flowchart of a method for efficient online simulation of a photoresist profile provided by the present invention.

In all the drawings, the same reference numerals are used to refer to the same elements or processes, wherein:
1—Division of photoresist reaction into steps, 2—Model construction process, 3—Model calibration process, 4—Model library establishment process, 5—Photoresist internal light intensity distribution I(x, y), 6—Wiener-Padé form sub-cascading module, 7—Wiener-Padé form sub-cascading module output Jₙ(x, y), 8—Wiener-Padé form, 9—Wiener base functions, 10—Wiener product functions, 11—Wiener sum functions, 12—Critical dimension or profile data obtained by simulation, 13—Model calibration parameters, 14—Sub-cascading module setting identity equation or simple linear operator square process, 15—Photoresist characterization system network, 16—Calibration parameter fixed sub-cascading module, 17—Calibration process convergence condition, 18—Optimization fitting algorithm, 19—Discrete variation process parameters, 20—Measured critical dimension or profile data, 21—Data extraction method based on library matching, and 22—Online simulation.

### DETAILED DESCRIPTION

To make the purpose, technical solution, and advantages of the present invention clearer, the present invention is further described in detail below in connection with the accompanying drawings and embodiments. It should be understood that the specific embodiments described herein are only used to explain the present invention, but not to limit the present invention.

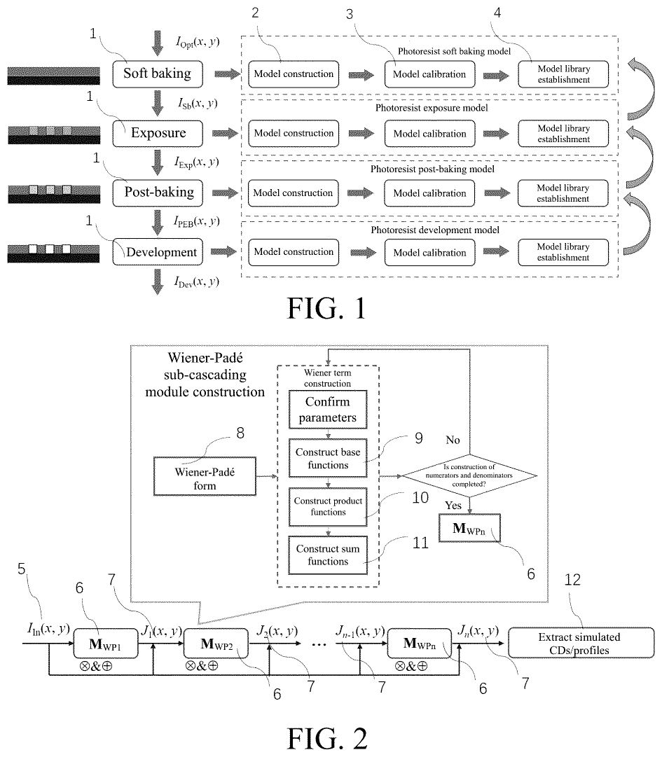

FIG. 1 is a schematic diagram of the inventive concept of universal photoresist modeling and calibration based on a Wiener-Padé multi-stage series system network provided by the present invention. As shown in FIG. 1, the inventive concept of the present invention is: firstly dividing a photoresist reaction process into several key stages, using a new idea of modeling a multi-stage series system network, and utilizing a joint calibration strategy based on a constrained quadratic convex optimization algorithm to provide a simulation means based on library matching and low-order multivariate polynomial equivalence of model parameters. The invention emphasizes and leverages universal advantages of the Wiener-Padé theory in the characterization of non-linear system response characteristics, thereby achieving accurate and efficient modeling and calibration of complex physical, optical, and chemical highly-nonlinear response characteristics of photoresists in different process flows, while avoiding over-fitting and reducing model complexity and redundancy.

FIG. 2 is a flowchart of a method for modeling a multi-stage series photoresist characterization system network provided by the present invention. As shown in FIG. 2, the method can be divided into the following steps:

Step 1: Divide a photoresist reaction process in a photolithography process flow into several stages Stageₙ, according to a modeling idea of a multi-stage series system network.

Preferably, rules for dividing the photoresist reaction process in the lithography process flow into stages include, but are not limited to, division according to an actual process sequence 1, such as soft baking, exposure, post-baking, and other processes; or division according to nonlinear orders: such as linear, quadratic, tertiary, etc.

Step 2: Starting from the first stage in the photolithography process flow, according to process flow characteristics corresponding to a current stage Stageₙ, construct a Wiener-Padé form sub-cascading module M_{WPn}, and add the Wiener-Padé form sub-cascading module to a multi-stage series photoresist characterization system network 15. A construction process 2 of a Wiener-Padé form sub-cascading module 6 includes the following sub-steps:
S2.1: According to the process flow characteristics corresponding to the current stage, respectively determine model parameters such as Wiener nonlinear orders and kernel function types and quantities of a numerator and a denominator in a Wiener-Padé form 8 sub-cascading module 6 approximation.

Preferably, the Wiener-Padé form 8 sub-cascading module 6 is constructed with the ratio of two Wiener sum function terms 11, and mainly includes the following forms:

$${M}_{WPn} [ {J}_{n - 1} ( x , y ) ] = \frac{{W}_{S}^{m} ( x , y )}{{W}_{S}^{d} ( x , y )} , {W}_{S}^{d} ( x , y ) \geq ε ( x , y ) > 0$$

$$or ,$$

$${M}_{WPn} [ {J}_{n - 1} ( x , y ) ] = \frac{{W}_{S}^{m} ( x , y )}{E + {W}_{S}^{d} ( x , y )} , E + {W}_{S}^{d} ( x , y ) \geq ε ( x , y ) > 0$$

wherein M_{WPn}[Jₙ₋₁(x, y)] is the Wiener-Padé form sub-cascading module 6 corresponding to the current stage Stager, Wₛ^{d}(x, y) and Wₛ^{m}(x, y) are the Wiener sum function terms 11 corresponding to the numerator and the denominator in the Padé approximation, respectively, ε(x, y) is a set positive threshold matrix to avoid an ill-conditioned Padé approximation, and E is a matrix where all elements are 1. It should be emphasized that for the first-stage Wiener-Padé form cascade module, a previous-stage input J₀(x, y)=I(x,y).

In addition, the model parameters such as the Wiener nonlinearity orders, and the kernel function types and quantities of the numerator and the denominator in the Padé approximation, etc. can be separately selected according to requirements, and do not have to be consistent. Since the Padé approximation has the property of simulating high-order nonlinear responses with the ratio of two low-order polynomials, the Wiener term nonlinear orders in the numerator and the denominator can be limited to a second order or lower to avoid the complexity and redundancy of the Wiener-Padé form sub-cascading module. In addition, the Wiener kernel function is generally a set of orthonormal base functions. In order to ensure rotational symmetry of the Wiener-Padé form sub-cascading module, generally the Wiener kernel function can be chosen from kernel function types with rotational symmetry such as a Hermite-Gaussian function or a Laguerre-Gaussian function.

S2.2: Use an output result Jₙ₋₁(x, y) of a previous-stage Wiener-Padé form sub-cascading module M_{WPn-1} as an input, to convolute with selected kernel functions k(x, y) of the numerator and the denominator in the Padé approximation, respectively, to acquire sub-cascading module linear base function terms W_{B}(x, y). The i^{th} Wiener linear base function term 9 in the numerator or the denominator in the sub-cascading module Padé approximation has the following form:

W_{Bi}(x,y)=Jₙ₋₁(x,y)⊗kᵢ(x,y)
where “⊗” is a convolution operator, and kᵢ(x, y) is the i^{th} kernel function in the denominator or the numerator in the Padé approximation.

S2.3: According to the Wiener nonlinearity orders, multiply point by point linear base function term arrangements and combinations, to construct Padé approximation numerator and denominator product function terms W_{P}(x, y) of different orders, respectively. The Wiener product function terms 10 of different orders in the numerator or the denominator of the sub-cascading module Padé approximation have the following form:
linear wiener product function: W_{Bi}(x, y);
quadratic Wiener product function: W_{Bi}(x, y)*W_{Bj}(x, y);
cubic Wiener product function: W_{Bi}(x, y)*W_{Bj}x, y)*W_{Bk}(x, y);
. . . ,
where “*” is a point-by-point multiplication operator, and the highest order of the Wiener product function term is a set Wiener nonlinear order.

S2.4: Acquire Padé approximation numerator and denominator Wiener coefficients, and perform weighted summation on the base function terms of different orders in the numerator and the denominator, respectively, to obtain a final Wiener sum function term W_{S}(x, y). The Wiener sum function term 11 in the numerator or the denominator of the cascading module Padé approximation has the following form:

$${W}_{S} = {\sum }_{k} {α}_{k} {W}_{Pk}$$

where, “αₖ” is a Wiener weighting coefficient corresponding to the k^{th} Wiener product function term in the numerator or the denominator of the Padé approximation.

S2.5: Use the acquired Wiener sum functions in the numerator and the denominator to complete construction of the final Wiener-Padé form sub-cascading module 6 in a Wiener-Padé approximation.

Step 3: Acquire the output result Jₙ₋₁(x, y) of the previous-stage Wiener-Padé sub-cascading module M_{WPn-1}, and convolute an original photoresist internal light intensity I(x, y) with the current Wiener-Padé form sub-cascading module to obtain a current sub-cascading module output Jₙ(x, y), where the sub-cascading module output 7 is obtained by the following form:

Jₙ(x,y)=β₀M_{WPn}[Jₙ₋₁(x,y)]+β₁[I(x,y)⊗k(x,y)]
where Jₙ(x, y) and Jₙ₋₁(x, y) are the outputs of the current- and previous-stage sub-cascading modules, respectively, βᵢ is a weighting coefficient between the output of the previous-stage cascading module and an action of the current connection module, I(x, y) represents the original photoresist internal light intensity distribution, k(x, y) is a convolution kernel with the original photoresist internal light intensity distribution, and the selected kernel function type can be selected according to actual application cases.

Step 4: Repeat steps 2 and 3 until all Wiener-Padé form sub-cascading modules 6 in the multi-stage series photoresist characterization system network 15 are added.

Step 5: Acquire an output result of the last stage Wiener-Padé form 8 sub-cascading module 6, and obtain photoresist profile Cₛ(x, y) or critical dimension CDₛ data 12 by using a photoresist reaction threshold T. Extraction of the photoresist profile or critical dimension data 12 mainly includes the following sub-steps:

S5.1: In order to ensure the accuracy of data extraction, first upsample the output result of the last stage Wiener-Padé form 8 sub-cascading module 6.

S5.2: For extraction of a photoresist profile simulation photoresist simulated profile C(x, y), possibly use a photoresist reaction threshold T to truncate the upsampled final output result into a simulated binary image I₂ₛ(x, y)), and extract the edge of I₂ₛ(x, y) to obtain C(x, y):

$${I}_{2 s} ( x , y ) = \{ \begin{matrix}0 , & J ( x , y ) - T \leq 0 \\ 1 , & J ( x , y ) - T > 0\end{matrix}$$

For extraction of the photoresist critical dimension CDₛ, possibly first extract a light intensity distribution curve on a ruler from the output result, extract critical dimension endpoints by using {Pᵢ(x, y); [L(Pᵢ)−T]*[L(Pᵢ₊₁)−T]<0}, and calculate the distance between the two endpoints to obtain the critical dimension data provided by simulation, where L(Pᵢ) represents a light intensity value at a critical dimension endpoint on the light intensity distribution curve.

S5.3: Propose result evaluation for the photoresist simulated profile, convert a measured profile into a binary image I₂ₘ(x, y) with inner 1 and outer 0, and perform an XOR Boolean operation on I₂ₘ(x, y) and I₂ₛ(x, y) to obtain a profile difference map I₂ₒᵣ(x, y). The simulated profile extraction result is evaluated using the following formula:

$$Δ EPE = \frac{Num [ {I}_{2 o r} ( x , y ) = 1 ]}{Num [ {I}_{2 o r} ( x , y ) ]} {d}_{pixel}$$

where Num represents a pixel count function, the numerator is the number of counted pixels with a value of 1, the denominator is the total number of counted pixels in the binary image, and dₚᵢₓₑₗ represents the length of each pixel.

The simulated critical dimension data extraction result is evaluated using the following formula:

$$Δ EPE = \sqrt{\frac{{\sum }_{1}^{N} {( {CD}_{s} - {CD}_{m} )}^{2}}{N}}$$

where CDₛ and CDₘ represent the simulated and measured critical dimensions, respectively, and N is the total number of CDₘ.

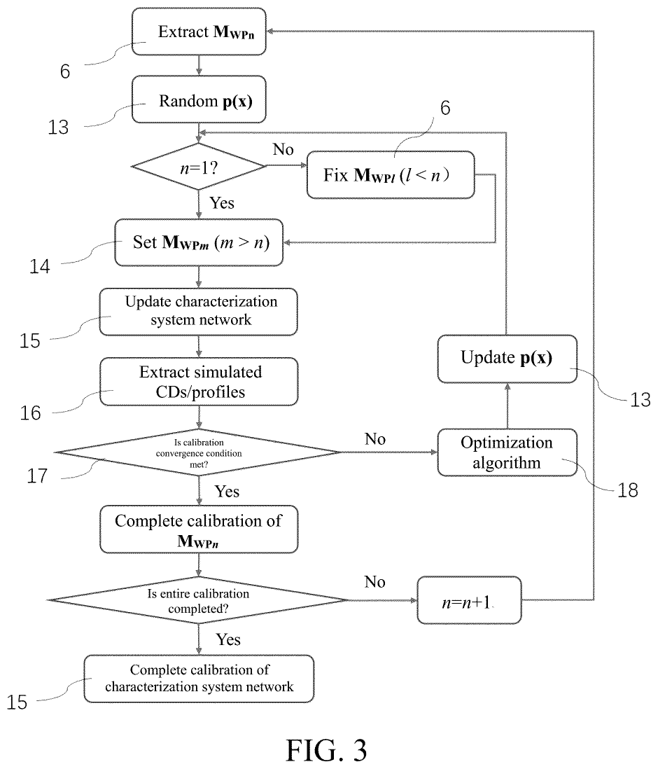

FIG. 3 is a flowchart of a method for calibrating a multi-stage series photoresist characterization system network provided by the present invention. As shown in FIG. 3, the method can be specifically divided into the following steps:

Step 1: Extract a Wiener-Padé form 8 sub-cascading module 6 corresponding to a stage Stage r from a multi-stage series photoresist characterization system network 15, confirm parameters 13 to be calibrated for the module, and randomly generate a set of non-zero parameter set p(x) to be calibrated for the current stage.

Step 2: Use preset parameters to set a sub-cascading module following the current stage to an identity equation or a simple linear operator 14. If the current stage is the first stage, then directly proceed to the next step; if the current stage is not the first stage, then use parameters obtained by calibration to fix the states 16 of all sub-cascading modules preceding the current stage, where the sub-cascading module can be set as the equation identity or the simple linear operator 15 in the following manner:
1) setting each Wiener coefficient in a Padé approximation numerator of the cascading module 6 to 0 or set the first term of a weighting coefficient between an output of a previous sub-cascading module and an action of the current module to 0, such that the module is equivalent to only an operator that only scales an input signal in an equal proportion;
2) directly treating the cascading module 6 as an equivalent unit operator, that is, outputting an input signal as it is;
3) treating the cascading module 6 as an equivalent bias operator, that is, performing addition or subtraction with respect to an input signal as a whole by the same constant.

Step 3: Bring the set of parameters to be calibrated p(x) into the current Wiener-Padé form 8 sub-cascading module 6 to complete update of the entire photoresist characterization system network 15.

Step 4: Input an original photoresist internal light intensity distribution I(x, y) into the characterization system network, obtain an output result of the last stage sub-cascading module, and in conjunction with a photoresist threshold, obtain photoresist simulation profile or critical dimension data 12.

Step 5: Compare and evaluate the photoresist profile or critical dimension data obtained by simulation and the corresponding data obtained by measurement. If ΔEPE does not meet a precision convergence condition 17 at this stage, update the parameter set p(x) according to a corresponding optimization algorithm 18, and return to step 3; if ΔEPE meets the precision convergence condition at this stage, it indicates that calibration of the current stage sub-cascading module is complete.

Step 6: Determine whether the current process is a final target process; if so, then end calibration of the characterization system network; otherwise, repeat steps 1 to 5 until calibration of all series sub-Wiener-Padé form 8 submodules 6 in the photoresist characterization system network 15 is complete.

Preferably, the optimization algorithm 18 for updating the parameter set p(x) can be any one of a least squares method, a genetic algorithm, a gradient method, and other parameter fitting methods according to the requirements of actual application cases. Methods for evaluation and comparison of the simulated data and the measured data are as follows:

For comparison and evaluation between the simulated photoresist profile and the measured profile, a constrained quadratic convex optimization algorithm can be used to obtain by comparison the difference between a light intensity distribution 5 corresponding to an actual profile point in the output result of the last stage sub-cascading module 6 and a threshold T:

$$\{ \begin{matrix}{‖ {W}_{S}^{m} [ C ( x , y ) ] - T \cdot \{ E + {W}_{S}^{d} [ C ( x , y ) ] \} ‖}_{1 / 2 / ∞} \leq {δ}_{C} \cdot \{ E + {W}_{S}^{d} [ C ( x , y ) ] \} \\ E + {W}_{S}^{d} ( x , y ) \geq ε ( x , y ) > 0\end{matrix} \}$$

where δ_{C} is a convergence threshold between the simulated profile and the actual profile; ∥ ∥_{1/2/∞} represents taking a 1 norm, a 2 norm, or an infinite norm.

For comparison and evaluation between the simulated critical dimension and the measured critical dimension of the photoresist, a constrained quadratic convex optimization algorithm can be used to obtain by comparison the differences between light intensity distributions at two measurement endpoints C and D and the threshold T:

$${‖ \frac{{M}_{WPn} [ CD ( {P}_{1} ) ] - T}{{M}_{WPn}^{′} [ CD ( {P}_{1} ) ]} - \frac{{M}_{WPn} [ CD ( {P}_{2} ) ] - T}{{M}_{WPn}^{′} [ CD ( {P}_{2} ) ]} + \vert {P}_{2} - {P}_{1} \vert - {CD}_{m} ‖}_{1 / 2 / ∞} \leq {δ}_{CD}$$

δ_{CD} is a convergence threshold between the simulated critical dimension and the actual critical dimension; P₁ and P₂ are the two endpoints of critical dimension measurement, respectively, and M′_{WPn} is the derivative of the output result of the last stage sub-cascading module in the CD direction.

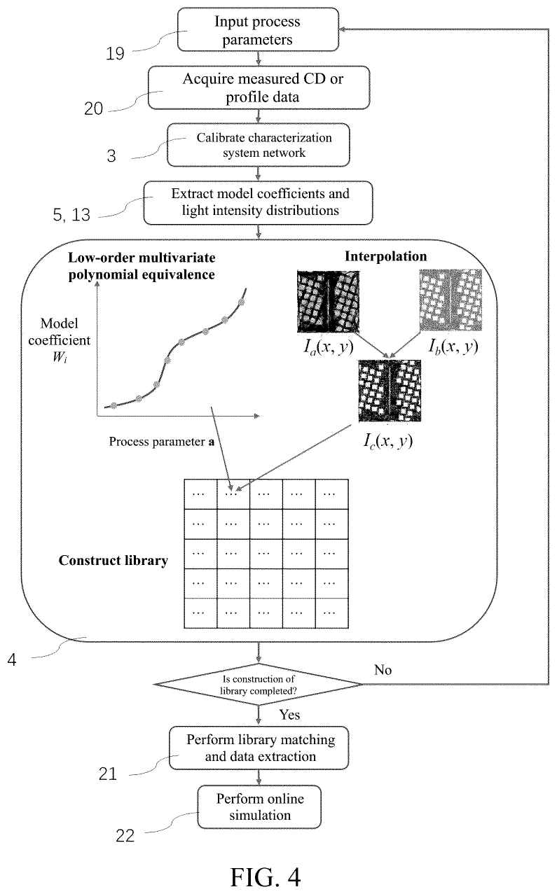

FIG. 4 is a flow chart of a method for efficient online simulation of a photoresist profile provided by the present invention. As shown in FIG. 4, the method can be specifically divided into the following steps:

Step 1: Acquire photoresist profile or critical dimension data 20 under a discrete distribution of a certain process parameter 19 in a variation interval.

Step 2: Use measured data 20 as an input, repeat a calibration process 3, to obtain a coefficient 13 of a Wiener-Padé form sub-cascading module 6 at each stage in the resist characterization system network 15 and a photoresist internal light intensity distribution 5 under discrete variation of the process parameter 19.

Step 3: Perform, according to the variation regularity of coefficients 13 of different sub-cascading modules 6, low-order multivariate polynomial equivalence on the discretely varying module coefficients, and establish a coefficient library 4 of sub-cascading modules under continuous variation of the process parameter.

Preferably, the low-order multivariable polynomial equivalence method specifically refers to using a target process parameter combination as an unknown parameter, selecting an appropriate varying low-order smooth continuous curve for fitting and equivalence according to the variation regularity of the coefficients 13 of the different sub-cascading modules 6, that is, linear fitting, quadratic curve fitting, parabolic fitting, etc. The module coefficient at any point in the discrete variation range of the process parameter can be calculated by obtaining a curve expression through fitting.

Step 4: Acquire a light intensity distribution 5 under any process parameter condition in the discrete variation interval of the process parameter 19 by using an interpolation method, and further establish a photoresist internal light intensity distribution library 4 under continuous variation of the process parameter.

Preferably, in an actual simulation application case, any one of methods such as linear interpolation, quadratic interpolation, and Fourier interpolation can be selected according to the requirements of accuracy and calculation speed. A method for acquiring the light intensity distribution under any process parameter condition in the discrete variation interval of the process parameter is as follows:

There are two measurement points a and bin the discrete variation interval of the process parameter 19, and the photoresist internal light intensity distribution 5 at the measurement points is Iₐ(x, y) and I_{b}(x, y), respectively, then a photoresist internal light intensity distribution I_{c}(x, y) at any point c between the measurement points a and b can be obtained by interpolation. Herein, the linear interpolation method is used as an example for illustration.

$${I}_{c} ( x , y ) = ( \frac{c - a}{b - a} ) {I}_{a} ( x , y ) + ( \frac{b - c}{b - a} ) {I}_{b} ( x , y )$$

Step 5: Repeat steps 1 to 4 to establish a module coefficient library 4 and a photoresist internal light intensity distribution library 4 corresponding to continuous variations of target process parameter combinations.

Step 6: At the simulation stage, using a process parameter 19 combination set for simulation as an index, and use a library matching method 21 to extract a corresponding system parameter 13 and photoresist internal light intensity distribution 5 under the process condition, and perform efficient online simulation prediction and evaluation 22 of a photoresist profile.

The present invention proposes a new idea of a multi-stage series system network for photoresist modeling, emphasizes and leverages universal advantages of the Wiener-Padé system theory in the characterization of non-linear system response characteristics, thereby achieving accurate and efficient modeling and calibration of complex physical, optical, and chemical highly non-linear response characteristics of photoresists in different process flows, while avoiding over-fitting and reducing model complexity and redundancy. A joint calibration strategy based on a constrained quadratic convex optimization algorithm is proposed, which can quickly converge to an optimal solution, while enabling a calibrated model to be more in line with actual physical conditions. A simulation strategy based on library matching and a low-order multi-variable polynomial equivalent method of model parameters is proposed, which can achieve efficient online simulation of continuous variations of multiple process parameters.

It can be easily understood by those skilled in the art that the foregoing description is only preferred embodiments of the present invention and is not intended to limit the present invention. All the modifications, identical replacements and improvements within the spirit and principle of the present invention should be in the scope of protection of the present invention.

1. A method for modeling a multi-stage series photoresist characterization system network, comprising:
S1, receiving designation of one or a plurality of target photoresist processes;
S2, establishing a corresponding series model for each target photoresist process; and
S3, cascading each series model according to a process sequence to form the multi-stage series characterization system network, wherein
step S2 comprises:
S21, receiving designation of the number of sub-cascading modules;
S22, constructing each Wiener-Padé form sub-cascading module; and
S23, sequentially connecting each Wiener-Padé form sub-cascading module in series to obtain a series model;
step S22 comprises:
S221, receiving designation of Wiener nonlinear orders, kernel function types, and quantities of a numerator and a denominator in a Padé approximation;
S222, convolving, according to the kernel function types and quantities of the numerator and the denominator, an output result of a previous-stage Wiener-Padé form sub-cascading module with selected kernel functions of the numerator and the denominator in the Padé approximation, to obtain base function terms of the numerator and the denominator;
S223, multiplying point by point, according to the Wiener nonlinear orders of the numerator and the denominator in the Padé approximation, base function term permutations and combinations of the numerator and the denominator to obtain base function terms of different orders in the numerator and the denominator;
S224, acquiring Wiener coefficients of the numerator and the denominator in the Padé approximation, and performing weighted summation on the base function terms of the different orders in the numerator and the denominator to obtain a numerator Wiener sum function term and a denominator Wiener sum function term; and
S225, constructing the numerator Wiener sum function term and the denominator Wiener sum function term in a Padé approximation form to obtain a Wiener-Padé form sub-cascading module.

2. The method according to claim 1, wherein the Wiener-Padé form sub-cascading modules are specifically as follows:
$${M}_{WPn} [ {J}_{n - 1} ( x , y ) ] = \frac{{W}_{S}^{m} ( x , y )}{{W}_{S}^{d} ( x , y )} , {W}_{S}^{d} ( x , y ) \geq ε ( x , y ) > 0$$
$$or$$
$${M}_{WPn} [ {J}_{n - 1} ( x , y ) ] = \frac{{W}_{S}^{m} ( x , y )}{E + {W}_{S}^{d} ( x , y )} , E + {W}_{S}^{d} ( x , y ) \geq ε ( x , y ) > 0$$
wherein M_{WPn} represents a current Wiener-Padé form sub-cascading module, Jₙ₋₁(x, y) represents an output result of a previous-stage Wiener-Padé form sub-cascading module, Wₛ^{m}(x, y) represents the numerator Wiener sum function term, Wₛ^{d}(x, y) represents the denominator Wiener sum function term, ε(x, y) represents a set positive threshold matrix to avoid an ill-conditioned Padé approximation, E represents a matrix where all elements are 1, and an previous-stage input to the first-stage Wiener-Padé form cascading module is an original photoresist internal light intensity distribution.

3. The method according to claim 2, wherein outputs of the Wiener-Padé form sub-cascading modules are as follows:
Jₙ(x,y)=β₀M_{WPn}[Jₙ₋₁(x,y)]+β₁[I(x,y)⊗k(x,y)]
wherein Jₙ(x, y) and Jₙ₋₁(x, y) represent outputs of the current and previous-stage sub-cascading modules respectively, β₀ and β₁ represent weighting coefficients between the output of the previous-stage sub-cascading module and an action of the current module, I(x, y) represents the original photoresist internal light intensity distribution, and k(x, y) represents a convolution kernel with the original photoresist internal light intensity distribution.

4. A method for calibrating a multi-stage series photoresist characterization system network, wherein the multi-stage series photoresist characterization system network is constructed using the method according to claim 1, the calibration method comprising:
T1, acquiring measured photoresist profile or critical dimension data; and
T2, using a joint calibration method based on a constrained quadratic convex optimization algorithm, cyclically comparing simulated photoresist profile or critical dimension data with the measured photoresist profile or critical dimension data, and sequentially calibrating a parameter of each sub-cascading module in the multi-stage series photoresist characterization system network.

5. The calibration method according to claim 4, wherein step T2 comprises:
T20, initializing a current process as the first target process;
T21, initializing a current module as the first Wiener-Padé sub-cascading module of the current process;
T22, determining a parameter to be calibrated for the current module, and randomly generating a set of non-zero parameters to be calibrated for the current process;
T23, determining whether the current process is the first target process, and if so, directly proceeding to T25; otherwise, proceeding to T24;
T24, using the parameter obtained by calibration to fix the states of all sub-cascading modules preceding the current process, and using preset parameters to set a sub-cascading module following the current process to an identity equation or a simple linear operator, and proceeding to T25;
T25, bringing the set of parameters to be calibrated into the current module to complete updating of the entire photoresist characterization system network;
T26, inputting the original photoresist internal light intensity distribution into the updated characterization system network, acquiring an output result of the last-stage sub-cascading module, and in conjunction with a photoresist threshold, acquiring the simulated photoresist profile or critical dimension data;
T27, comparing the photoresist profile or critical dimension data obtained by simulation with the corresponding measured data; if a current process accuracy convergence condition is not met, updating the calibrated parameter set and returning to step T25; otherwise, determining whether the current module is the last-stage sub-cascading module of the current process, and if so, proceeding to T28; otherwise, updating the current module to a next sub-cascading module of the current process and proceeding to step T22; and
T28, determining whether the current process is a final target process, and if so, indicating that the system network calibration is concluded; otherwise, updating the current process to the next target process and proceeding to step T21.

6. The calibration method according to claim 4, wherein the using preset parameters to set a sub-cascading module following the current process to an identity equation or a simple linear operator in step T24 is any of the following:
1) setting each Wiener coefficient in a Padé approximation numerator of the sub-cascading module to 0 or setting the first term of a weighting coefficient between an output of a previous sub-cascading module and an action of the current module to 0, such that the module is equivalent to an operator that only scales an input signal in an equal proportion;
2) directly treating the sub-cascading module as an equivalent unit operator, that is, outputting an input signal as it is;
3) treating the sub-cascading module as an equivalent bias operator, that is, performing addition or subtraction with respect to an input signal as a whole by the same constant.

7. The calibration method according to claim 4, wherein the method for data comparison in step T27 is specifically as follows:
T271, upsampling an output result of the last Wiener-Padé form sub-cascading module;
T272, using a photoresist reaction threshold T to truncate the upsampled final output result into a simulated binary image I₂ₛ(x, y);
extracting from the output result a light intensity distribution curve L(x, y) on a ruler, extracting a critical dimension endpoint Pᵢ(x, y) by using {Pᵢ(x, y); [L(Pᵢ)−T]*[L(Pᵢ₊₁)−T]<0}, and calculating the distance between two endpoints as the simulated critical dimension data CDₛ, wherein L(Pᵢ) represents a light intensity value at a critical dimension endpoint on the light intensity distribution curve;
T273, converting the measured profile to a binary image I₂ₘ(x, y) with inner 1 and outer 0, and performing an XOR Boolean operation on I₂ₘ(x, y) and I₂ₛ(x, y) to obtain a profile difference map I₂ₒᵣ(x, y), and evaluating a simulated profile extraction result by using the following formula:
$$Δ EPE = \frac{Num [ {I}_{2 o r} ( x , y ) = 1 ]}{Num [ {I}_{2 o r} ( x , y ) ]} {d}_{pixel}$$
wherein Num represents a pixel count function, the numerator in the above formula is the number of counted pixels with a value of 1, the denominator in the above formula is the total number of counted pixels in the binary image, and dₚᵢₓₑₗ represents the length of each pixel;
evaluating a simulated critical dimension data extraction result by using the following formula:
$$Δ EPE = \sqrt{\frac{{\sum }_{1}^{N} {( {CD}_{s} - {CD}_{m} )}^{2}}{N}}$$
wherein CDₛ and CDₘ represent the simulated and measured critical dimensions respectively, and N is the total number of CDₘ.

8. The calibration method according to claim 4, wherein
for comparison and evaluation between the simulated photoresist profile and the measured photoresist profile, a constrained quadratic convex optimization algorithm is used to obtain by comparison the difference between a light intensity distribution corresponding to an actual profile point in the output result of the last stage sub-cascading module and a threshold:
$$\{ \begin{matrix}{‖ {W}_{S}^{m} [ C ( x , y ) ] - T \cdot \{ E + {W}_{S}^{d} [ C ( x , y ) ] \} ‖}_{1 / 2 / ∞} \leq {δ}_{C} \cdot \{ E + {W}_{S}^{d} [ C ( x , y ) ] \} \\ E + {W}_{S}^{d} ( x , y ) \geq ε ( x , y ) > 0\end{matrix} \}$$
for comparison and evaluation between the simulated photoresist critical dimension and the measured photoresist critical dimension, a constrained quadratic convex optimization algorithm is used to compare and measure the differences between measured light intensity distributions at two ends C and D and the threshold:
$${‖ \frac{{M}_{WPn} [ CD ( {P}_{1} ) ] - T}{{M}_{WPn}^{′} [ CD ( {P}_{1} ) ]} - \frac{{M}_{WPn} [ CD ( {P}_{2} ) ] - T}{{M}_{WPn}^{′} [ CD ( {P}_{2} ) ]} + \vert {P}_{2} - {P}_{1} \vert - {CD}_{m} ‖}_{1 / 2 / ∞} \leq {δ}_{CD}$$
wherein Wₛ^{m}(x, y) represents a numerator Wiener sum function term, Wₛ^{d}(x, y) represents a denominator Wiener sum function term, C(x, y) represents the simulated profile obtained by performing edge extraction on the simulation binary image, T represents a photoresist reaction threshold, E represents a matrix where all elements are 1, δ_{CD} represents a convergence threshold between the simulated profile and the measured profile; ∥ ∥_{1/2/∞} represents a 1 norm, a 2 norm, or an infinite norm; M_{WPn} represents the current Wiener-Padé form sub-cascading module, M′_{WPn} represents the derivative of the output result of the last-stage sub-cascading module in the CD direction, CD( ) represents the coordinates at the critical end point; P₁ and P₂ represent the two endpoints of the measured critical dimension, respectively.

9. A method for efficient online simulation of a photoresist profile, comprising:
R1, acquiring photoresist profile or critical dimension data under discrete distributions of different process parameters in different variation intervals;
R2, using measured data in a variation interval of the same process parameter as an input, using the calibration method according to claim 4 to repeatedly correct a photoresist characterization system network, so as to obtain a coefficient of a Wiener-Padé form sub-cascading module at each stage in the photoresist characterization system network and a photoresist internal light intensity distribution under discrete variation of the process parameter;
R3, performing, according to the variation regularity of coefficients of different sub-cascading modules, low-order multivariate polynomial equivalence on the discretely varying module coefficients, and establishing a coefficient library of sub-cascading modules under continuous variation of the process parameter;
R4, acquiring a light intensity distribution under any process parameter condition in the discrete variation interval of the process parameter by using an interpolation method, and establishing a photoresist internal light intensity distribution library under continuous variation of the process parameter;
R5, repeating steps R1 to R4 to establish a module coefficient library and a photoresist internal light intensity distribution library corresponding to continuous variations of target process parameter combinations; and
R6, at a simulation stage, using a process parameter combination set for simulation as an index, using a library matching method to extract a corresponding system parameter and photoresist internal light intensity distribution under the process condition, and bringing the system parameter and internal light intensity distribution into the photoresist characterization system network, to perform efficient online simulation prediction and evaluation of a photoresist profile.

10. A system for efficient online simulation of a photoresist profile, comprising a processor and a memory;
the memory being configured to store a computer program or instructions;
the processor being configured to execute the computer program or instructions in the memory such that the method according to claim 9 is performed.
